(19) United States
(12) Patent Application Publication
(10) Pub. No.: US 2006/0230326 A1
(43) Pub. Date: Oct. 12, 2006

(54) Method for re-using test cases through standardization and modularity

(76) Inventors: Matthew P. Potts, Citrus Heights, CA (US); Mark Gravel, Roseville, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/083,737

(22) Filed: Mar. 18, 2005

(51) Int. Cl. G01R 31/28; G06F 11/00

(52) U.S. Cl. 714/741

(57) ABSTRACT

A method is disclosed for creating test cases for simulating the design and operation of an integrated circuit having operational functionality that requires adherence to a multiplicity of operating rules, wherein the test cases are created in such a way that modularized component test cases can be combined and comprises creating and storing a plurality of component test cases for simulating the design and various aspects of the operational functionality of the integrated circuit, wherein each of the component test cases have data defining a predetermined configuration and a predetermined stimulus, each component test case being written to comply with the operating rules, and selectively combining and running two or more of the plurality of component test cases as a combined test case.

### BACKGROUND OF THE INVENTION

The present invention generally relates to the design and testing of integrated circuits.

Normally, when one runs a simulation of an integrated circuit design, there are two conceptual parts, one of which is the simulation of the desired actual design that is intended to carry out an intended functionality, such as an application specific integrated circuit, i.e., an ASIC, which may be used in a product such as a network router, network switch and the like. The other conceptual part is the stimulus that is applied to the simulation to determine if it operates as it should. In the case of an ASIC being designed as a network switch, the stimulus would be many types of network traffic for which switch is designed and would therefore be encountered during use.

Formerly, there was no concept of separating the two parts, i.e., the design and stimulus, from a test point of view. A test was often designed to configure the circuit design to behave in a particular way and then certain types of stimulus was applied. In other words, the test had certain kinds of data applied to the simulated design by the appropriate stimulus, and the resulting test data was read and analyzed. It was important to insure that the test case itself, which is usually represented as a file, has the appropriate stimulus in it, e.g., Ethernet traffic in the case of network switch test case. Since a switch generally has multiple ports as well as multiple cards, a test case can have stimulus that comprises different kinds of traffic applied to different ports, different sized packets, different packets applied at different rates, as well as other variables that can be varied.

Historically, test cases did not have any formal language in which they are written. Most of the time they were just sets of data that was accumulated as a result of sticking desired data in a file somewhere. However, in the circumstances in which the present invention is particularly applicable, the data is quite complex. In fact, a typical test case file does not have much data in it. Instead, the file is generally comprised of descriptions of other pieces of code that need to be pulled together in certain combinations. If the wrong combination is pulled in, the test case will not work properly. This is because there are rules that are prescribed which define what pieces of code can be pulled in to create the right kind of stimulus. In the case of a test case for the network switch example, it would comprise the rules of real network traffic. For example, there may be a rule that dictates that there will never be a circumstance where there is a sequence of A code, followed by B code, followed by B code (an ABB sequence). So if B code is applied, the switch has to know that if it follows an AB sequence, it would be an invalid sequence. There are tremendous numbers of such rules in actual network traffic as is known by those skilled in the art.

### SUMMARY OF THE INVENTION

The preferred embodiment of the present invention is principally a method of creating test cases for simulating the design and operation of an integrated circuit having operational functionality that requires adherence to a multiplicity of operating rules, wherein the test cases are created in such a way that modularized component test cases can be combined and comprises creating and storing a plurality of component test cases for simulating the design and various aspects of the operational functionality of the integrated circuit, wherein each of the component test cases have data defining a predetermined configuration and a predetermined stimulus, each component test case being written to comply with the operating rules, and selectively combining and running two or more of the plurality of component test cases as a combined test case.

### DETAILED DESCRIPTION OF THE PREFERRED EMBODIMENTS

There is a high level verification language e which simulates and verifies a design that is marketed by the Verisity Company of Mountain View, Calif., which allows one to specify everything about stimulus that would be expected to be used in a test case. Normally, in the prior art, when one wanted to devise a test case to test some specific functionality, it would be designed with the appropriate and applicable rules being known and acknowledged. There currently is no known mechanism to combine two tests such as test A and test B because there has not been any contemplation or motivation to combine them in the past, and therefore there has not been any necessity to determine the validity or compatibility of the combination. If it is desired to combine two tests, it is difficult to know what rules apply because it is difficult to know what rules exist in each test.

Broadly stated, the preferred embodiment of the present invention involves modularizing the stimulus that is used in test cases in such a way that the stimulus can be gathered hierarchically. A simplistic example is to write a first test case that applies packet A as a stimulus, and write a second test case to apply packet B as a stimulus. If another test was desired to apply packet A followed by packet B and another packet A, it can be more efficiently done by defining such an ABA test as applying test A, then applying test B, and then applying test A again. This is in contrast to writing another complete ABA test. If one were to then want to have a subsequent test of BAB, it can be similarly run by applying in sequence the already existing test B, test A and test B in that order. Of course, the ABA and BAB sequences are assumed to be valid sequences, i.e., they comply with all of the rules of the particular application for which a test case is being conducted.

The responsibility for having valid sequences begins with the smallest piece of code, i.e., test A, for example. Each of the small pieces of code must necessarily have to comply with all of the rules, since they may become components of more extensive sequences. Test A may be a 10 gigabit speed packet with a 64 byte size. Test B may be a type of packet that goes to every port. It is intuitively expected that these two tests may be run together.

Packets have data in them, called the payload. There are also fields in a packet that mean very specific things to a network switch itself, such as what port the packet is to go to, and the size of the packet. While packets are data, they have many fields which are necessary to the proper functioning of the network switch, i.e., what the relationships are between many fields. Part of the data can actually dictate how the switch is configured. There may be hundreds of protocols, i.e., Ethernet for one, that a switch may or may not understand. Ethernet is perhaps the lowest level protocol, and there may be many higher level protocols on top of that. Depending upon how sophisticated the switch is, the switch may understand many different levels of protocol.

It should be understood that a test case is normally considered to be a set of stimulus to a design, and has not a considered to be pieces of code. However, if a test case were written as if it were code, then modularization concepts that are applied in standard coding concept can be applied to the concept of a test case. It is generally correct that more complex test cases can be created by combining individual test cases and thereby reducing the amount of work that is required to create the complex test cases.

A particular test case will usually contain configuration information, i.e., how many ports are to be simulated, as well as stimulus It is generally a given that configuration data as well as stimulus code is capable of being overwritten. If test A is written in and it uses 5 ports, and is followed by test B which uses 6 ports, the one that is read in later will control with regard to configuration data. If tests A and B are combined in an AB sequence, but the test B configuration is not what is desired, another test C with the desired configuration (and perhaps no stimulus) can be added to obtain the desired configuration and stimulation data from tests A and B is layered on top of one another.

While the forgoing discussion applies, it is also preferred that configuration data be specified to establish the configuration before any stimulus is applied during the test. The order of running a resulting modularized test case that is put together from individual test cases is to gather all of the configuration data from each of the tests that are to combined to determine the configuration, and then apply the stimulus to the resulting test case.

The preferred embodiment of the present invention attempts to treat configuration data as being separate from stimulus, i.e., configuration related code is attempted to be separated from stimulus related data. Thus, anything that is related to the packet itself is generally defined as stimulus and anything that is related to ports is configuration data. However, certain information may be overlapped or duplicated by the other. For example, configuration data may specify that data coming into a certain specified port should be sent to another particular specified port. However, a packet itself may also have a particular setting in it that provides the same routing.

Configuration data typically includes the number and size of memory buffers, the number of ports, certain delays that are required during specified operations, the configuration of registers and coding specifying the rules of valid operation. Registers generally comprise single bit configuration fields which dictate specific operations when set or not set, such as whether a network is operating in a flow control mode, which is also known as a lossy versus lossless mode. In the lossy mode, one bit specifies that if a buffer is full, all data that is being sent to that particular buffer is dropped. In a lossless mode, it is set differently to specify that a signal should be sent back to the sender of the data to stop sending data.

The rules are coded in the e verification language and also in the design of the ASIC. In the test case, the configuration data sets data for its operation and the code that is present in the e verification language determines if valid traffic patterns or configurations exist. If not valid, an error notification is generated.

The test case itself does not determine if it is valid. A test can be examined for its settings, but the significance of a setting may not be apparent in terms of what is really happening as a result of the setting. A test writer must know what particular rules apply for a particular test or sequence of tests. With knowledge of the applicable rules, the content of two or more particular test configurations and stimulus can also be understood by the test writer, and enable the writer to determine the validity of the test case. As an example, there may be a line in a test that states “added e-code” which may push a file onto a list named added e-code, with the name of the file being “turn on lossless.e”. That will change the setting, which is what the test will then use. The “Turn on lossless.e” file has “e” code in it that sets the particular bit for flow control.

The determination as to whether a test is passed can be made in several ways. The basic way is that the design has certain conditions, which if not satisfied, results in an error notification. The verification code e can also monitor such conditions and generate an error notification. The test writer can also define that if a certain condition is met, an error notification is generated, even though the certain defined condition is not normally an invalid operation. A log file is generally produced that contains all of the error notifications. It is possible to write code that can check for any particular condition, and base a pass or fail decision on the presence or absence of such a condition. Normally, a test is failed if errors are generated.

While various embodiments of the present invention have been shown and described, it should be understood that other modifications, substitutions and alternatives are apparent to one of ordinary skill in the art. Such modifications, substitutions and alternatives can be made without departing from the spirit and scope of the invention, which should be determined from the appended claims.

Various features of the invention are set forth in the appended claims.

What is claimed is:

1. A method of creating test cases for simulating the design and operation of an integrated circuit having operational functionality that requires adherence to a multiplicity of operating rules, wherein the test cases are created in such a way that modularized component test cases can be combined, said method comprising the steps of:
creating a first component test case for simulating the design and at least a part of the functionality of an integrated circuit, wherein said first component test case has data defining a first predetermined configuration and a first predetermined stimulus;
creating a second component test case for simulating the design and at least a part of the functionality of an integrated circuit, wherein said second component test case has data defining a second predetermined configuration and a second predetermined stimulus; and,
combining and running said first and second component test cases as a combined test case.

2. A method as defined in claim 1 wherein said step of combining and running said first and second component test cases further comprises:
determining the configuration of the combined test case; and
running the combined test case using the first and second predetermined stimulus.

3. A method as defined in claim 1 wherein the step of determining the configuration of the combined test case comprises gathering the configuration data from each of the tests that are to combined to determine the configuration of the combined test case.

4. A method as defined in claim 2 wherein the configuration of the combined test case is the configuration of the last component test case to be combined to form said combined test case.

5. A method as defined in claim 2 wherein configuration data can be overwritten, the configuration of the combined test case therefore being determined by the configuration of the last component test case to be combined to form said combined test case.

6. A method as defined in claim 1 wherein any component test case, including said first and second component test cases, can comprise a predetermined configuration and an absence of stimulus.

7. A method as defined in claim 1 wherein said configuration data is separate and independent from said stimulus data.

8. A method as defined in claim 1 wherein said integrated circuit is a network switch that processes data packets from various protocols

9. A method as defined in claim 8 wherein said stimulus data comprises data related generally to data packets themselves.

10. A method as defined in claim 8 wherein configuration data comprises data relating generally to ports of a network switch.

11. A method as defined in claim 8 wherein configuration data includes data relating to one or more of the characteristics of the number and size of memory buffers, the number of ports, the time delays that are required during specified operations, the configuration of registers, the coding specifying the rules of valid operation, single bit registers defining configuration fields which dictate specific operations when set or not set.

12. A method as defined in claim 1 further comprising storing said component test cases for use in subsequent simulations.

13. A method of creating test cases for simulating the design and operation of an integrated circuit having operational functionality that requires adherence to a multiplicity of operating rules, wherein the test cases are created in such a way that modularized component test cases can be combined, said method comprising the steps of:
creating and storing a plurality of component test cases for simulating the design and various aspects of the operational functionality of the integrated circuit, wherein each of said component test cases have data defining a predetermined configuration and a predetermined stimulus, each component test case being written to comply with said operating rules;
selectively combining and running two or more of said plurality of component test cases as a combined test case.

14. A method as defined in claim 13 wherein said combining and running step further comprises gathering the configuration data from each of the tests that are to combined to determine the configuration of the combined test case.

15. A method as defined in claim 13 wherein said configuration data can be overwritten, the configuration of the combined test case therefore being determined by the configuration of the last component test case to be combined to form said combined test case.

16. A method as defined in claim 13 wherein said operation functionality is a network switch having a plurality of ports.

17. A method as defined in claim 13 further comprising monitoring at least one predetermined condition during the running said combined test case and generating an error notification if said condition is not satisfied.

18. A method as defined in claim 17 further comprising producing a log file that contains error notifications.
